(19) United States
(12) Patent Application Publication
(10) Pub. No.: US 2011/0192463 A1
(43) Pub. Date: Aug. 11, 2011

(54) CIGS SOLAR CELL STRUCTURE AND METHOD FOR FABRICATING THE SAME

(76) Inventor: Chuan-Lung Chuang, Taoyuan (TW)

(21) Appl. No.: 13/089,281

(22) Filed: Apr. 18, 2011

Related U.S. Application Data
(63) Continuation-in-part of application No. 12/407,780, filed on Mar. 19, 2009.

(51) Int. Cl. H01L 31/0264

(52) U.S. Cl. 136/262

(57) ABSTRACT

A copper/indium/gallium/selenium (CIGS) solar cell structure and a method for fabricating the same are provided. The CIGS solar cell structure includes a substrate, a molybdenum thin film layer, an alloy thin film layer, and a CIGS thin film layer. The alloy thin film layer is provided between the molybdenum thin film layer and the CIGS thin film layer, serving as a conductive layer of the CIGS solar cell structure. The alloy thin film layer is composed of a variety of high electrically conductive materials (such as molybdenum, copper, aluminum, and silver) in different atomic proportions.

### CROSS-REFERENCES TO RELATED APPLICATIONS

This is a continuation-in-part application for the application Ser. No. 12/407,780 filed on Mar. 19, 2009, which is incorporated herewith by reference.

### BACKGROUND OF THE INVENTION

1. Field of the Invention

The present invention relates generally to a copper/indium/gallium/selenium (CIGS) solar cell structure and a method for fabricating the same, and more particularly, to a CIGS solar cell structure including an alloy thin film layer disposed between a molybdenum thin film layer and a CIGS thin film layer, and a method for fabricating the same.

2. The Prior Arts

CIGS thin film solar cells are being expected as one type of the most potentially low cost solar cells. Comparing with the other current thin film battery technologies, a CIGS thin film solar cell has higher efficiency. Currently, a small size CIGS thin film solar cell unit may achieve an efficiency of up to 19%, and a large size one may achieve an efficiency of up to 13%. Further, the CIGS thin film solar cell can be fabricated by a chemical vapor deposition (CVD) process which is adapted for low cost and large size processing. Furthermore, the CIGS thin film solar cell is radiation resistible and light weighted.

FIG. 1 is a schematic diagram illustrating a conventional CIGS thin film solar cell 1. Referring to FIG. 1, the CIGS thin film solar cell 1 includes a substrate 10, a molybdenum thin film layer 20, and a CIGS thin film layer 80. The molybdenum thin film layer 20 is deposited by sputtering on the substrate 10 for serving as a back electrode. The CIGS thin film layer 80 is then configured by a synchronizing evaporation deposition and selenylation process on the molybdenum thin film layer 20 for serving as a light absorbing layer.

However, the CIGS thin film layer 80 directly deposited upon the molybdenum thin film layer 20 often peels off therefrom and is featured with unsatisfactory conductivity and resistance coefficient.

### SUMMARY OF THE INVENTION

A primary objective of the present invention is to provide a CIGS solar cell structure. The CIGS solar cell structure includes a substrate, a molybdenum thin film layer, an alloy thin film layer, and a CIGS thin film layer. According to the present invention, the alloy thin film layer is provided between the molybdenum thin film layer and the CIGS thin film layer, serving as a conductive layer of the CIGS solar cell structure. The alloy thin film layer is composed of a variety of high electrically conductive materials (such as molybdenum, copper, aluminum, and silver) in different atomic proportions.

A further objective of the present invention is to provide a method for fabricating a CIGS solar cell structure. The method includes sputtering a molybdenum thin film layer upon a substrate, and then continuously depositing an alloy thin film layer onto the molybdenum thin film layer by bombarding targets toward the molybdenum thin film layer with a sputtering machine. The sputtering machine is adapted for precisely performing the thin film deposition and improving the uniformity of the alloy mixed by different metals for preparing the alloy thin film layer. The targets include high electrically conductive materials, such as molybdenum, copper, aluminum, and silver. Thereafter, a CIGS thin film layer is then deposited on the alloy thin film layer.

Accordingly, the present invention is adapted for solving the problems of the conventional technologies as discussed above, so as to improve the electrical conductivity, reduce the resistance coefficient of the molybdenum thin film layer, thus reducing the thickness thereof so as to avoid the peeling off of the CIGS thin film layer.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a schematic diagram illustrating a conventional CIGS thin film solar cell;

FIG. 2 is a structural diagram illustrating a CIGS solar cell structure according to an embodiment of the present invention;

FIG. 3 is a schematic diagram illustrating a first embodiment of the present invention;

FIG. 4 is a schematic diagram illustrating a second embodiment of the present invention;

FIG. 5 is a schematic diagram illustrating a third embodiment of the present invention; and

FIG. 6 is a schematic diagram illustrating a fourth embodiment of the present invention.

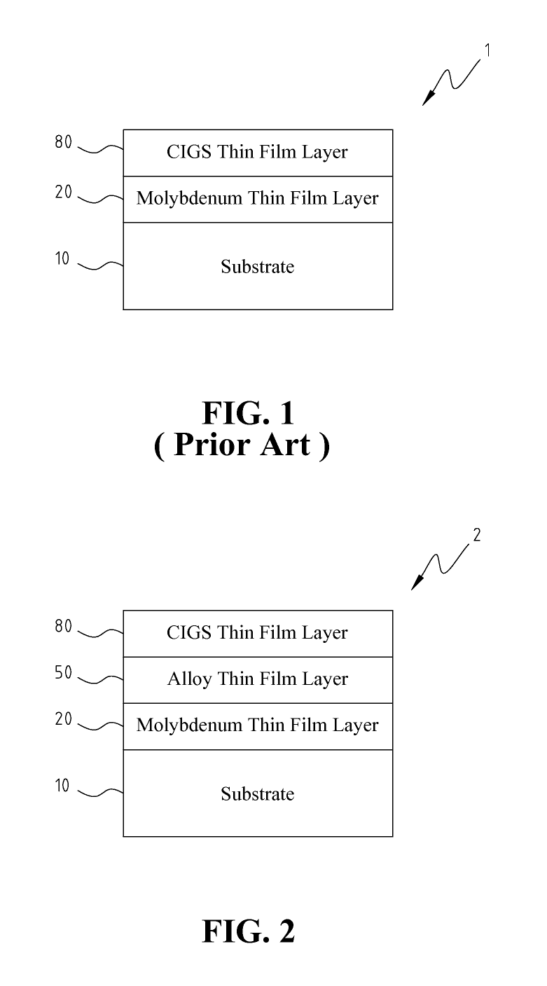

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

FIG. 2 is a structural diagram illustrating a CIGS solar cell structure according to an embodiment of the present invention. Referring to FIG. 2, the CIGS solar cell structure includes a substrate 10, a molybdenum thin film layer 20, an alloy thin film layer 50, and a CIGS thin film layer 80. The substrate 10, the molybdenum thin film layer 20, the alloy thin film layer 50, and the CIGS thin film layer 80 are sequentially bottom-up stacked one upon another. The substrate 10 is a glass substrate or a flexible metal substrate. The composition of the CIGS thin layer 80 is Cu_{y}In₍₁₋ₓ₎GaₓSe₂, where y=0.75˜1.0 and x=0.15˜0.35.

According to an aspect of the current embodiment, the alloy thin film layer 110 for example includes molybdenum and aluminum, in which the atomic proportion of molybdenum to aluminum is about 6˜9:1˜2. When the alloy thin film layer 50 has a thickness ranging from 0.1 to 0.25 μm, the electrical conductivity of the alloy thin film layer 50 ranges from 20×10⁶/mΩ to 25×10⁶/mΩ.

According to another aspect of the current embodiment, the alloy thin film layer 110 for example includes molybdenum and copper, in which the atomic proportion of molybdenum to copper is about 5˜8:1˜4. When the alloy thin film layer 50 has a thickness ranging from 0.1 to 0.25 μm, the electrical conductivity of the alloy thin film layer 50 ranges from 30×10⁶/mΩ to 35×10⁶/mΩ.

According to a further aspect of the current embodiment, the alloy thin film layer 50 for example includes molybdenum, copper and aluminum, in which the atomic proportion of molybdenum, copper, and aluminum is about 5˜7:3˜5:1˜2.

When the alloy thin film layer 50 has a thickness ranging from 0.1 to 0.25 μm, the electrical conductivity of the alloy thin film layer 50 ranges from 30×10⁶/mΩ to 35×10⁶/mΩ.

According to still another aspect of the current embodiment, the alloy thin film layer 50 for example includes molybdenum, copper, aluminum, and silver, in which the atomic proportion of molybdenum, copper, aluminum, and silver is about 5˜7:3˜4:1˜1.5:2˜2.5. When the alloy thin film layer 50 has a thickness ranging from 0.1 to 0.25 μm, the electrical conductivity of the alloy thin film layer 50 ranges from 35×10⁶/mΩ to 40×10⁶/mΩ.

It should be noted that the CIGS thin film layer 80 of the CIGS solar cell structure is configured on the alloy thin film layer by a synchronizing evaporation deposition and selenylation process.

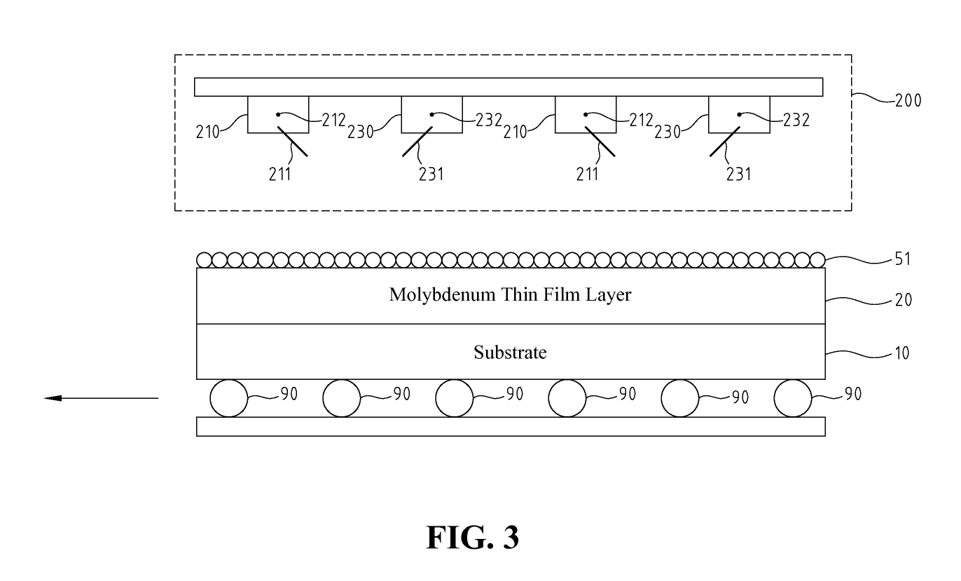

FIG. 3 is a schematic diagram illustrating a first embodiment of the present invention. Referring to FIG. 3, at first, a molybdenum thin film layer 20 is deposited upon a substrate 10 by a sputtering process. The substrate 10 together with the molybdenum thin film layer 20 configured thereupon are secured on a roller set 90, and driven to move along a direction indicated by the arrow. A sputtering machine 200 is provided over the substrate 10 having the molybdenum thin film layer 20 configured thereupon. The sputtering machine 200 includes a plurality of ejector sets. Each of the ejector sets includes a molybdenum target ejector 211, and an aluminum target ejector 231. A molybdenum target 212 is provided in a molybdenum target chamber 210. An aluminum target 232 is provided in an aluminum target chamber 230. The molybdenum target ejector 211 is positioned beneath the molybdenum target chamber 210, and the aluminum target ejector 231 is positioned beneath the aluminum target chamber 230. Each of the target chambers is provided with a sputtering gun (not shown in the drawings). The powers of the sputtering guns can be adjusted. According to the powers of the sputtering guns, the amounts of the targets ejected from the target ejectors can be adjusted for adjusting the alloy mixing proportion. Preferably, the target ejectors are adapted for continuously sputtering on the molybdenum thin film layer 20. In such a way, an alloy thin film layer 51 can be configured with an improved uniformity. The alloy thin film layer 51 preferably has a thickness ranging from 0.1 to 0.25 μm, in which the alloy proportion between the molybdenum and the aluminum ranges from 9:1 to 3:1.

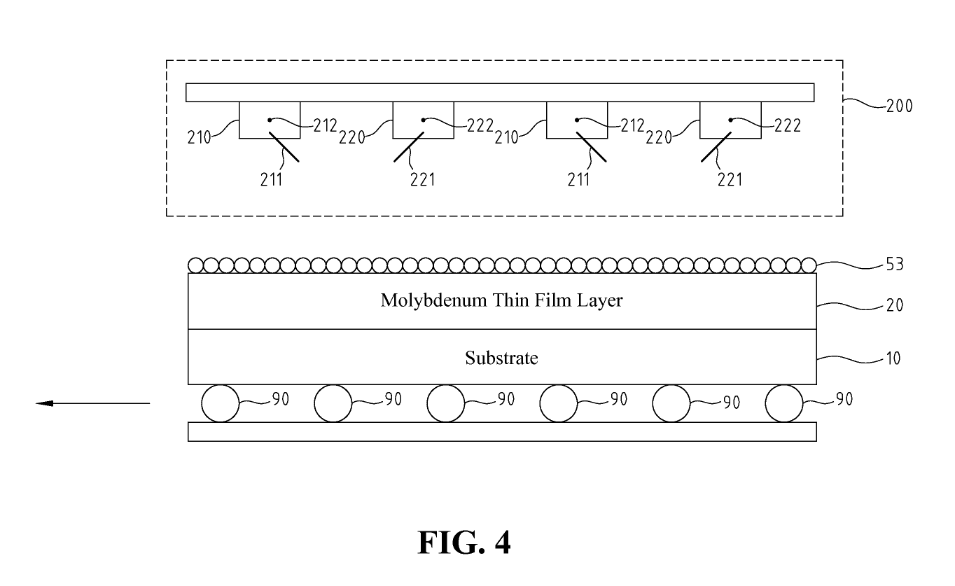

FIG. 4 is a schematic diagram illustrating a second embodiment of the present invention. Referring to FIG. 4, the current embodiment is similar to the first embodiment as shown in FIG. 3, except that copper is employed for substituting the aluminum employed in the first embodiment so that the a molybdenum/copper alloy thin film layer 53 is obtained instead of the molybdenum/aluminum alloy thin film layer 51. The copper target 232 is provided in the copper target chamber 230, while the copper target ejector 221 is positioned beneath the copper target chamber 230. The sputtering ejectors continuously sputter until the obtained molybdenum/copper alloy thin film layer 53 achieves a thickness ranging from 0.1 to 0.25 μm, in which the alloy atomic proportion between the molybdenum and the copper ranges from 8:1 to 1.25:1.

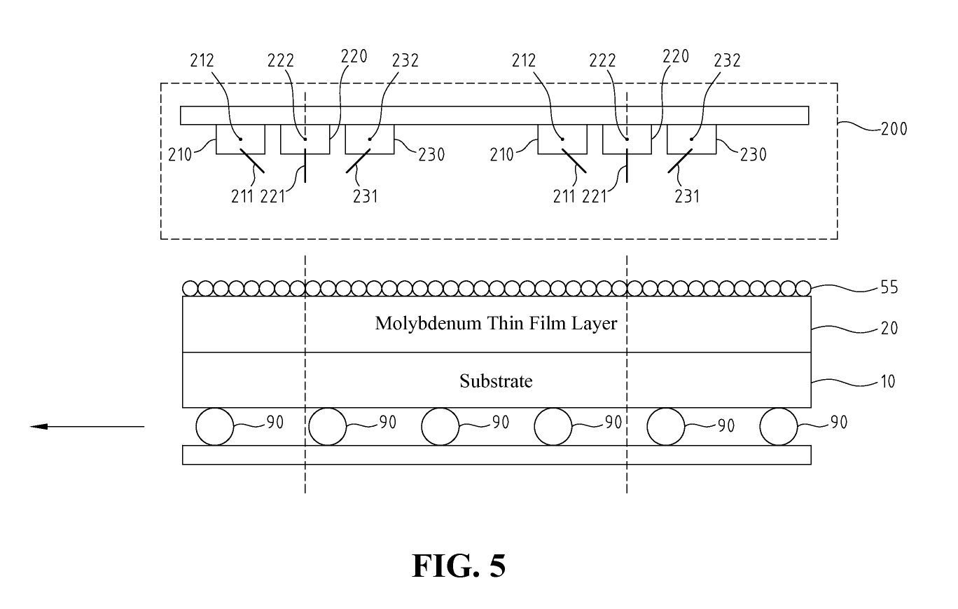

FIG. 5 is a schematic diagram illustrating a third embodiment of the present invention. Referring to FIG. 5, the current embodiment is similar to the first embodiment as shown in FIG. 3, except that molybdenum, copper, and aluminum are employed for configuring molybdenum/copper/aluminum alloy thin film layer 55 instead of that the molybdenum and aluminum are used for configuring the molybdenum/aluminum alloy thin film layer 51. The sputtering ejectors continuously sputter until the obtained molybdenum/copper/aluminum alloy thin film layer 55 achieves a thickness ranging from 0.1 to 0.25 μm, in which the atomic proportion of molybdenum, copper, and aluminum is about 5˜7:3˜5:1˜2.

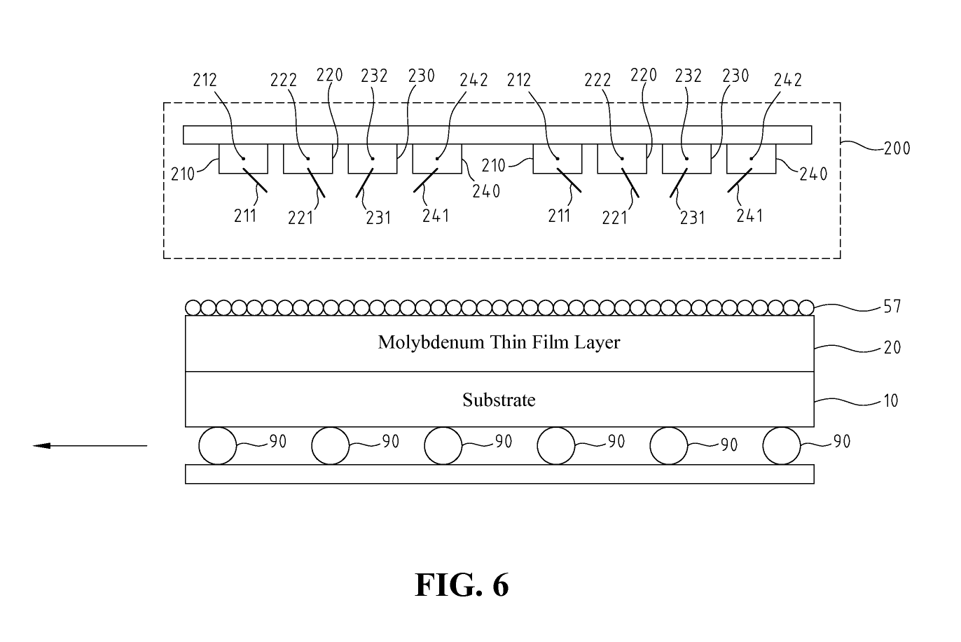

FIG. 6 is a schematic diagram illustrating a fourth embodiment of the present invention. Referring to FIG. 6, the current embodiment is similar to the first embodiment as shown in FIG. 3, except that molybdenum, copper, aluminum, and silver are employed for configuring molybdenum/copper/aluminum/silver alloy thin film layer 57 instead of that the molybdenum and aluminum are used for configuring the molybdenum/aluminum alloy thin film layer 51. The sputtering ejectors continuously sputter until the obtained molybdenum/copper/aluminum/silver alloy thin film layer 57 achieves a thickness ranging from 0.1 to 0.25 μm, in which the atomic proportion of molybdenum, copper, aluminum, and silver is about 5˜7:3˜4:1˜1.5:2˜2.5.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A copper/indium/gallium/selenium (CIGS) solar cell structure, comprising:
a substrate;
a molybdenum thin film layer configured on the substrate;
a molybdenum/aluminum alloy thin film layer configured on the molybdenum thin film layer by continuously sputtering with a sputtering machine; and
a CIGS thin film layer deposited on the molybdenum/aluminum alloy thin film layer;
wherein an atomic proportion of molybdenum to aluminum in the molybdenum/aluminum alloy layer is 6˜9:1˜2, and the molybdenum/aluminum alloy layer has a thickness ranging from 0.1 to 0.25 μm, and an electrical conductivity ranging from 20×10⁶/mΩ to 25×10⁶/mΩ.

2. The CIGS solar cell structure according to claim 1, wherein the substrate is a glass substrate or a flexible metal substrate.

3. The CIGS solar cell structure according to claim 1, wherein the CIGS layer has a composition in the form of Cu_{y}In₍₁₋ₓ₎GaₓSe₂, with y=0.75˜1.0 and x=0.15˜0.35.

4. A copper/indium/gallium/selenium (CIGS) solar cell structure, comprising:
a substrate;
a molybdenum thin film layer configured on the substrate;
a molybdenum/copper alloy thin film layer configured on the molybdenum thin film layer by continuously sputtering with a sputtering machine; and
a CIGS thin film layer deposited on the molybdenum/copper alloy thin film layer;
wherein an atomic proportion of molybdenum to copper in the molybdenum/copper alloy layer is 5˜8:1˜4, and the molybdenum/copper alloy layer has a thickness ranging from 0.1 to 0.25 μm, and an electrical conductivity ranging from 30×10⁶/mΩ to 35×10⁶/mΩ.

5. The CIGS solar cell structure according to claim 4, wherein the substrate is a glass substrate or a flexible metal substrate.

6. The CIGS solar cell structure according to claim 4, wherein the CIGS layer has a composition in the form of Cu_{y}In₍₁₋ₓ₎GaₓSe₂, with y=0.75˜1.0 and x=0.15˜0.35.

7. A copper/indium/gallium/selenium (CIGS) solar cell structure, comprising:
a substrate;
a molybdenum thin film layer configured on the substrate;
a molybdenum/copper/aluminum alloy thin film layer configured on the molybdenum thin film layer by continuously sputtering with a sputtering machine; and
a CIGS thin film layer deposited on the molybdenum/copper/aluminum alloy thin film layer;
wherein an atomic proportion of molybdenum to copper to aluminum in the molybdenum/copper/aluminum alloy layer is 5˜7:3˜5:1˜2, and the molybdenum/copper/aluminum alloy layer has a thickness ranging from 0.1 to 0.25 μm, and an electrical conductivity ranging from 30×10⁶/mΩ to 35×10⁶/mΩ.

8. The CIGS solar cell structure according to claim 7, wherein the substrate is a glass substrate or a flexible metal substrate.

9. The CIGS solar cell structure according to claim 7, wherein the CIGS layer has a composition in the form of Cu_{y}In₍₁₋ₓ₎GaₓSe₂, with y=0.75˜1.0 and x=0.15˜0.35.

10. A copper/indium/gallium/selenium (CIGS) solar cell structure, comprising:
a substrate;
a molybdenum thin film layer configured on the substrate;
a molybdenum/copper/aluminum/silver alloy thin film layer configured on the molybdenum thin film layer by continuously sputtering with a sputtering machine; and
a CIGS thin film layer deposited on the molybdenum/copper/aluminum/silver alloy thin film layer;
wherein an atomic proportion of molybdenum to copper to aluminum to silver in the molybdenum/copper/aluminum/silver alloy layer is 5˜7:3˜4:1˜1.5:2˜2.5, and the molybdenum/copper/aluminum/silver alloy layer has a thickness ranging from 0.1 to 0.25 μm, and an electrical conductivity ranging from 35×10⁶/mΩ to 40×10⁶/mΩ.

11. The CIGS solar cell structure according to claim 10, wherein the substrate is a glass substrate or a flexible metal substrate.

12. The CIGS solar cell structure according to claim 10, wherein the CIGS layer has a composition in the form of Cu_{y}In₍₁₋ₓ₎GaₓSe₂, with y=0.75˜1.0 and x=0.15˜0.35.
